(19) United States
(12) Patent Application Publication
(10) Pub. No.: US 2026/0353743 A1
(43) Pub. Date: Nov. 5, 2026

(54) NANOSTRUCTURE FIELD-EFFECT TRANSISTOR DEVICE HAVING ISOLATION STRUCTURES UNDER SOURCE/DRAIN REGIONS COMPRISING A LINER LAYER AND A MULTI-LAYERED DIELECTRIC LAYER OVER THE LINER LAYER

(71) Applicant: Taiwan Semiconductor Manufacturing Co., Ltd., Hsinchu (TW)

(72) Inventors: Mu-Chieh Chang, Hsinchu (TW); Shu Ling Liao, Taichung (TW); Zhen-Cheng Wu, Hsinchu (TW); Sung-En Lin, Xionglin Township (TW); Tze-Liang Lee, Hsinchu (TW)

(21) Appl. No.: 19/740,437

(22) Filed: Jul. 14, 2026

Related U.S. Application Data
(62) Division of application No. 18/331,305, filed on Jun. 8, 2023.

(51) Int. Cl. H10D 64/01; H10D 30/01; H10D 30/43; H10D 30/67; H10D 62/10

(52) U.S. Cl. CPC H10D 64/018; H10D 30/014; H10D 30/43; H10D 30/6735; H10D 62/121; H10D 64/017

(57) ABSTRACT

A semiconductor device includes: a substrate; a fin protruding above the substrate; a gate structure over the fin; source/drain regions over the fin and on opposing sides of the gate structure; channel layers over the fin and between the source/drain regions, where the gate structure wraps around the channel layers; and isolation structures under the source/drain regions, where the isolation structures separate the source/drain regions from the fin, where each of the isolation structures includes a liner layer and a dielectric layer over the liner layer, where the dielectric layer has a plurality of sublayers.

### PRIORITY CLAIM AND CROSS-REFERENCE

This application is a divisional of U.S. patent application Ser. No. 18/331,305, filed on Jun. 8, 2023 and entitled “Nanostructure Field-Effect Transistor Device Having Isolation Structures under Source/Drain Regions Comprising a Liner Layer and a Multi-Layered Dielectric Layer over the Liner Layer,” which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A-5C, 6A-6C, 7A-7C, 8A-8C, 9A, 9B, 10A, 10B, 11A, 11B, 12A, 12B, 13A, and 13B are cross-sectional views of a nanostructure field-effect transistor (NSFET) device 100 at various stages of manufacturing, in accordance with an embodiment.

FIGS. 14A-14C illustrate various embodiments of the isolation structures of the NSFET device 100.

FIG. 15 illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are discussed in the context of forming isolation structures for a nanostructure field-effect transistor (NSFET) device. The principle of the disclosure may also be applied for forming isolation structures in other types of devices, such as planar devices, fin field-effect transistor (FinFET) devices, and so on.

In accordance with some embodiments, an isolation structure is formed under a source/drain region of an NSFET device to separate the source/drain region from the underlying fin, thereby reducing leaking current of the device formed. The isolation structure may include a U-shaped liner material, and a dielectric layer on the liner material. The dielectric layer may comprise silicon nitride. In some embodiments, the dielectric layer of the isolation structure includes a plurality of sublayers, where each sublayer comprises silicon nitride and has a respective atomic ratio between nitrogen and silicon. There may be a gradient in the atomic ratios of the sublayers of the dielectric layer. The thicknesses and/or the atomic ratios of the sublayers of the dielectric layer may be tuned to modify properties (e.g., K value, etch rate, electrical isolation property) of the isolation structure.

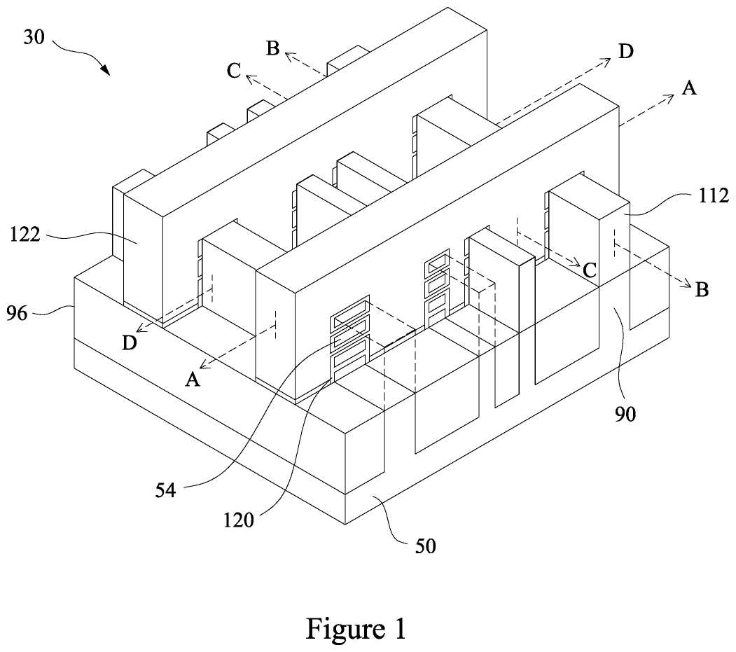

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures refer to these reference cross-sections for clarity.

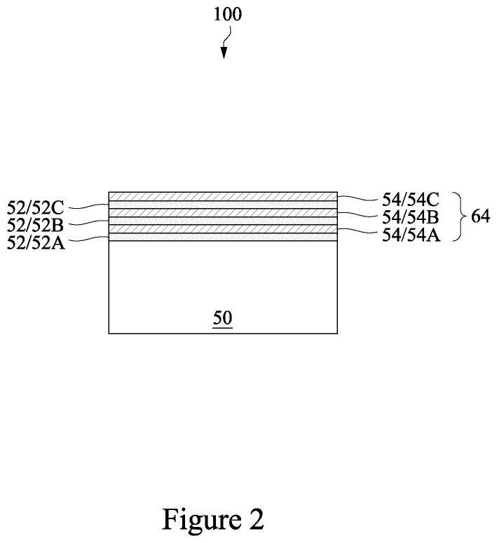

FIGS. 2, 3A, 3B, 4A, 4B, 5A-5C, 6A-6C, 7A-7C, 8A-8C, 9A, 9B, 10A, 10B, 11A, 11B, 12A, 12B, 13A, and 13B are cross-sectional views of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. The multi-layer stacks 64 (which may also be referred to as an epitaxial material stack) will be patterned to form channel regions of an NSFET in subsequent processing. In particular, the multi-layer stacks 64 will be patterned and etched to form horizontal nanostructures (e.g., nanosheets or nanowires), with the channel regions of the resulting NSFET including multiple horizontal nanostructures.

The multi-layer stacks 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

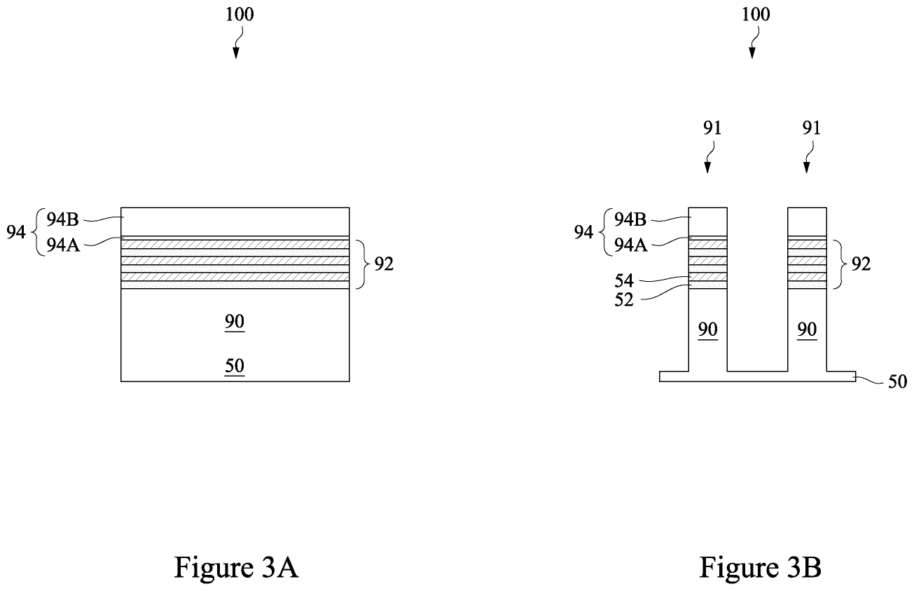

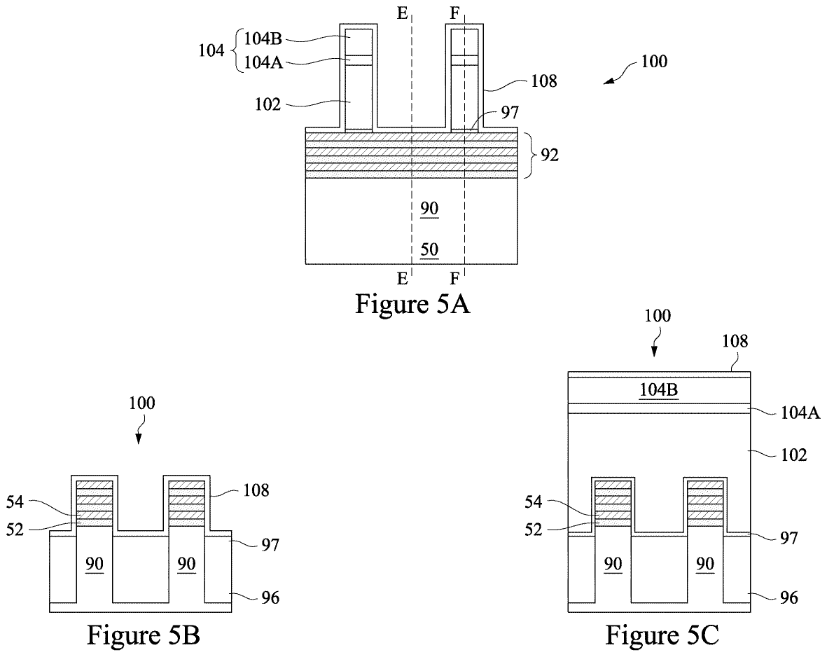

FIGS. 3A, 3B, 4A, 4B, 5A-5C, 6A-6C, 7A-7C, 8A-8C, 9A, 9B, 10A, 10B, 11A, 11B, 12A, 12B, 13A, and 13B are cross-sectional views of the NSFET device 100 at subsequent stages of manufacturing, in accordance with an embodiment. FIGS. 3A, 4A, 5A, 6A, 7A, 8A, 9A, 10A, 11A, 12A, and 13A are cross-sectional views along cross-section B-B in FIG. 1. FIGS. 3B, 4B, 5C, 6C, 7C, 8C, 9B, 10B, 11B, 12B, and 13B are cross-sectional views along cross-section A-A in FIG. 1. FIGS. 5B, 6B, 7B and 8B are cross-sectional views along cross-section D-D in FIG. 1. Two fins and two gate structures are illustrated in the figures as a non-limiting example, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned substrate 50 forms the fins 90, as illustrated in FIGS. 3A and 3B. Therefore, in the illustrated embodiment, the layer stack 92 also includes alternating layers of the first semiconductor material 52 and the second semiconductor material 54, and the fin 90 is formed of a same material (e.g., silicon) as the substrate 50.

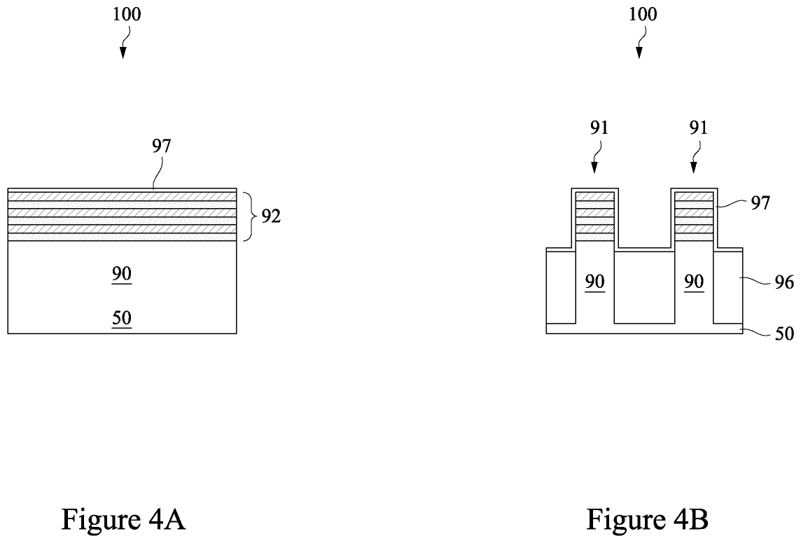

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively.

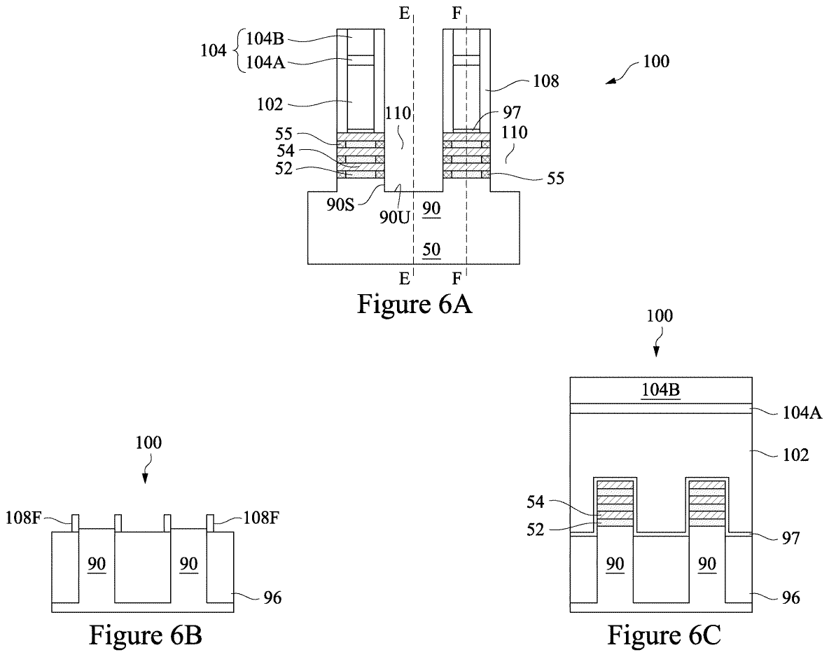

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108. In addition, after the anisotropic etching process to form the gate spacers 108, remaining vertical portions of the gate spacer layer 108 along sidewalls of the fins 90 form fin spacers 108F, as illustrated in FIG. 6B.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layers disposed outside the sidewall recesses of the first semiconductor material 52. The remaining portions of the inner spacer layers (e.g., portions disposed inside the sidewall recesses of the first semiconductor material 52) form inner spacers 55.

As illustrated in FIG. 6A, the openings 110 expose sidewalls of the second semiconductor material 54, sidewalls of the inner spacers 55, and upper surfaces 90U of the fins 90. In embodiments where the openings 110 extend into the fins 90, the openings 110 may also expose sidewalls 90S of the fins 90, which sidewalls 90S are formed by the removal of upper portions of the fins 90.

FIGS. 6B and 6C illustrate cross-sectional views of the NSFET device 100 in FIG. 6A along cross-sections E-E and F-F, respectively. In FIG. 6B, the portions of the gate spacer layer 108 disposed on the upper surface of the STI regions 96 between neighboring fins 90 are completely removed by the anisotropic etching process used for forming the gate spacers 108. In some embodiments, portions of the gate spacer layer 108 are left (e.g., remain) between neighboring fins 90 on the upper surface of the STI regions 96. Those portions of the gate spacer layer 108 may be left because the anisotropic etching process discussed above may not completely remove the gate spacer layer 108 disposed between neighboring fins 90, due to the small distance between the neighboring fins 90 reducing efficiency of the anisotropic etching process.

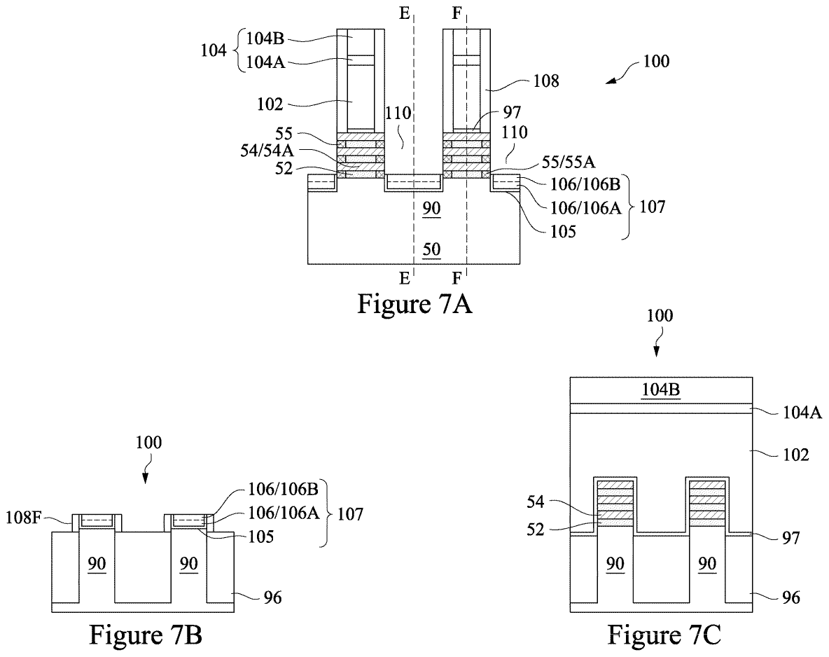

Next, in FIGS. 7A-7C, isolation structures 107 are formed at the bottoms of the openings 110. In the illustrated embodiment, each of the isolation structures 107 includes a dielectric liner layer 105 and a dielectric layer 106 formed on the dielectric liner layer 105. The dielectric liner layer 105 (may also be referred to as a dielectric liner material, or a liner layer) is a dielectric material having a first dielectric constant, and the dielectric layer 106 has a second dielectric constant different from the first dielectric constant. The dielectric layer 106 may be a single-layer dielectric layer, or may include a plurality of sublayers. In embodiments where the dielectric layer 106 includes a plurality of sublayers, the second dielectric constant of the dielectric layer 106 refers to an overall (e.g., an average) dielectric constant for the plurality of sublayers.

In some embodiments, the dielectric liner layer 105 is a conformal dielectric material along the bottoms and the lower sidewalls of the openings 110. The dielectric liner layer 105 may be formed of a suitable dielectric material, such as Si_{w}CₓO_{y}N_{z}, where w, x, y, and z determine the atomic percentages of the different elements (e.g., Si, C, O, or N) of the dielectric material. A dielectric constant (also referred to as the k value) of the dielectric liner layer 105 is smaller than 7, in some embodiments. The dielectric constant of the dielectric liner layer 105 may be chosen to be smaller than that of the dielectric layer 106, which advantageously reduces the overall dielectric constant of the isolation structures 107 and improves the RC performance of the NSFET device formed. Besides Si_{w}CₓO_{y}N_{z}, other suitable dielectric materials, such as silicon oxide, may also be used. In the illustrated embodiments, the dielectric liner layer 105 is a single-layer dielectric material (e.g., having a homogenous composition), although a multi-layered structure for the dielectric liner layer 105 is also contemplated and is fully intended to be included within the scope of the present disclosure.

The dielectric liner layer 105 may be formed by a suitable formation method, such as CVD, ALD, combinations thereof, or the like. The as-deposited dielectric liner layer 105 may completely cover the bottoms and the sidewalls of the openings 110. A suitable etching process, such as a dry etch, wet etch, combinations thereof, or the like, may be performed next to remove upper portions of the deposited dielectric liner layer 105, such that after the etching process, the remaining portions of the dielectric liner layer 105 cover the bottoms and the lower sidewalls of the openings 110, as illustrated in FIG. 7A. In some embodiments, the etching process is controlled such that after the etching process, an upper surface of the dielectric liner layer 105 distal from the substrate 50 is below a lower surface of a lowermost (e.g., closest to the substrate 50) semiconductor material 54A. For example, the upper surface of the dielectric liner layer 105 is between an upper surface and a lower surface of an inner spacer 55A, where the inner spacers 55A is a lowermost inner spacer (e.g., closest to the substrate 50). This allows the isolation structure 107 to be formed with a sufficient thickness to provide good electrical isolation, while at the same time ensures that sidewalls of the second semiconductor material 54 are exposed by the isolation structure 107, such that in subsequent processing, source/drain regions 112 can be epitaxially grown on the sidewalls of the second semiconductor material 54. In some embodiments, the removal of the upper portions of dielectric liner layer 105 is achieved using a same etching process discussed hereinafter for removing the upper portions of the dielectric layer 106.

Next, the dielectric layer 106 is formed in the openings 110 on the dielectric liner layer 105. In some embodiments, the dielectric layer 106 is formed of silicon nitride (SiₓN_{y}), where an atomic ratio between nitrogen and silicon (e.g., y:x) is between 0 and about 1.33. The atomic ratio measures the ratio of the number of nitrogen atoms to the number of silicon atoms in the dielectric layer 106. Note that the x and y used in the notation of SiₓN_{y} is independent from the x and y used in the notation of Si_{w}CₓO_{y}N_{z}. As will be discussed in more details hereinafter, the dielectric layer 106 may be a single-layer dielectric material (e.g., having a homogenous composition), or a multi-layered dielectric material (e.g., having a non-homogenous composition) comprising a plurality of sublayers. The number of sublayers, the thickness of each sublayer, and/or the properties (e.g., dielectric constant, etch rate) of each sublayer may be adjusted to achieve target performance criteria for the NSFET device formed. The dielectric layer 106 may be formed by depositing the dielectric material of the dielectric layer 106 on the dielectric liner layer 105, then performing an etching process to remove upper portions of the deposited dielectric material. Details are discussed hereinafter. Discussion herein uses silicon nitride as an example material for the dielectric layer 106, with the understanding that other suitable dielectric materials may also be used, and the principle disclosed herein (e.g., structures and formation methods for the dielectric layer 106) may also be applied to other suitable dielectric material for the dielectric layer 106.

In an embodiment, the dielectric layer 106 is formed using a suitable deposition process, such as plasma-enhanced CVD (PECVD). The parameters (e.g., pressure, temperature, combinations thereof, or the like) of the deposition process are tuned such that the deposition rate of the dielectric layer 106 is non-uniform. For example, the deposition rate of dielectric layer 106 along sidewalls of the openings 110 increases along a direction from the tops of the openings 110 toward the bottoms of the openings 110. As a result, the thickness of the dielectric layer 106 along the sidewalls of the openings 110 increases gradually from the tops of the openings 110 toward the bottoms of the openings 110. In some embodiments, the dielectric layer 106 along opposing sidewalls of the openings 110 merge at the bottom portions of the openings 110 to fill the bottom portions of the openings 110 (e.g., due to the lower portions of the dielectric layer 106 having larger thicknesses), and upper sidewall portions (e.g., portions formed along upper sidewalls of the openings 110) of the dielectric layer 106 do not merge and remain separate. In addition, or alternatively, the parameters of the deposition process may be tuned to achieve a gradient in the etch rate of the dielectric layer 106 for a subsequent etching process. For example, the etch rate of the dielectric layer 106 along the sidewalls of the openings 110 may decrease gradually from the tops of the openings 110 toward the bottoms of the openings 110. In other words, there is a gradient(s) in the thicknesses and/or in the etch rates of different portions of the dielectric layer 106 along the vertical direction.

In another embodiment, the dielectric layer 106 is formed using a suitable deposition process, such as CVD. The parameters (e.g., pressure, temperature, combinations thereof, or the like) of the deposition process may be tuned such that the thickness of the dielectric layer 106 increases gradually from the tops of the openings 110 toward the bottoms of the openings 110. Next, the deposited dielectric layer 106 is treated by a plasma process to modify the properties (e.g., etch rate) of the deposited dielectric layer 106. The parameters of the plasma process (e.g., pressure, temperature, combinations thereof, or the like) may be tuned such that after the plasma treatment, the etch rate of the dielectric layer 106 for the subsequent etching process decreases gradually from the tops of the openings 110 toward the bottoms of the openings 110. Therefore, after the deposition process and the plasma treatment process, there is a gradient(s) in the thicknesses and/or in the etch rates of different portions of the dielectric layer 106 along the vertical direction.

In some embodiments, the dielectric layer 106 is a single-layer dielectric material (e.g., silicon nitride) formed by a CVD-type deposition process (e.g., CVD, or PECVD) using a first precursor comprising silicon and a second precursor comprising nitrogen. A mixing ratio between the first precursor and the second precursor is chosen at a value (e.g., at a fixed target value) to achieve a target atomic ratio between nitrogen and silicon for the dielectric layer 106 formed. Besides the mixing ratio, other parameters of the deposition process, such as deposition time, flow rates of the precursors, temperature, pressure, combinations thereof, or the like, may be adjusted to achieve a target thickness for the dielectric layer 106.

In some embodiments, the dielectric layer 106 is a multi-layered dielectric material (e.g., silicon nitride) formed by a CVD-type deposition process (e.g., CVD, or PECVD) using a first precursor comprising silicon and a second precursor comprising nitrogen. The dielectric layer 106 includes a plurality of sublayers formed successively over the dielectric liner layer 105. A mixing ratio between the first precursor and the second precursor is chosen at a respective value (e.g., a respective fixed target value) for each sublayer of the dielectric layer 106, such that each sublayer of the dielectric layer 106 has its respective atomic ratio between nitrogen and silicon. Besides mixing ratio, other parameters of the deposition process, such as deposition time, flow rate of the precursors, temperature, pressure, combinations thereof, or the like, may be adjusted for each sublayer to achieve a target thickness for each sublayer of the dielectric layer 106.

Due to the differences in the thicknesses and/or etch rates of different portions of dielectric layer 106, an etching process, such as dry etch, wet etch, combinations thereof, or the like, is performed next to easily remove (e.g., completely remove) the upper sidewall portions of the dielectric layer 106, and only bottom portions of the dielectric layer 106 (e.g., at the bottom portions of the openings 110) remain to form the isolation structure 107 with the dielectric liner layer 105, as illustrated in FIG. 7A. In some embodiments, the etching process is controlled such that after the etching process is finished, the upper surface of the remaining portions of the dielectric layer 106 is substantially level with the upper surface of the dielectric liner layer 105.

In some embodiments, when the atomic ratio between nitrogen and silicon is increased, the dielectric constant of the dielectric layer 106 decreases, and the etch rate of the dielectric layer 106 increases. Therefore, by adjusting the atomic ratio between nitrogen and silicon, and/or by adjusting the thickness of the dielectric layer 106 (or by adjusting the atomic ratio and/or thickness of each sublayer of the dielectric layer 106), the properties of the isolation structure 107 can be tuned to achieve a balance between etch resistance and low dielectric constant. For example, a suitable range for the atomic ratio between nitrogen and silicon for a single-layer dielectric layer 106 may be between 0 (in which case the dielectric layer 106 becomes silicon) and about 1.33. If the atomic ratio is too high, the etch rate of the dielectric layer 106 may be too high, and therefore, the dielectric layer 106 may be damaged (e.g., etched) by subsequent etching process(es). For dielectric layer 106 having a multi-layered structure, there are more tunable parameters, such as the number of sublayers, the atomic ratio and the thickness of each sublayer, and in addition, the atomic ratio between nitrogen and silicon for each sublayer may have a wider range than the range between 0 and 1.33. Furthermore, the thickness and/or the material of the dielectric liner layer 105 may also be tuned to achieve an overall dielectric constant and etching resistance level for the isolation structure 107. Various embodiments of the isolation structure 107 are discussed below.

The isolation structures 107 in FIG. 7A are used to illustrate a single-layer dielectric layer 106 (when the dashed horizontal lines are ignored), or a dual-layer dielectric layer 106, with the dashed horizontal lines indicating the interface between a first sublayer layer 106A and a second sublayer 106B of the dielectric layer 106. In an embodiment where the dual-layer dielectric layer 106 has a first sublayer 106A and a second sublayer 106B, the second sublayer 106B (e.g., the upper sublayer) has an atomic ratio between nitrogen and silicon that is higher than that of the first sublayer 106A (e.g., the lower sublayer). For example, the atomic ratio between nitrogen and silicon for the second sublayer 106B may have a value of 1.3, and the atomic ratio between nitrogen and silicon for the first sublayer 106A may have a value of 1.8. The etch rates for the second sublayer 106B and the first sublayer 106A are 2 angstroms/min and 12 angstroms/min, respectively. The dielectric constants for the second sublayer 106B and the first sublayer 106A are 7.3 and 6.5, respectively. Therefore, the second sublayer 106B acts as a protection layer (due to its low etch rate) for the first sublayer 106A, and the first sublayer 106A helps to reduce the overall dielectric constant of the isolation structure 107.

FIG. 7B shows the NSFET device 100 of FIG. 7A along the cross-section E-E in FIG. 7A. In FIG. 7B, the isolation structures 107 are shown as being formed on the upper surfaces of the fins 90 and between pairs of fin spacers 108F. In some embodiments, the isolation structures 107 are also formed on the upper surfaces of the STI regions 96.

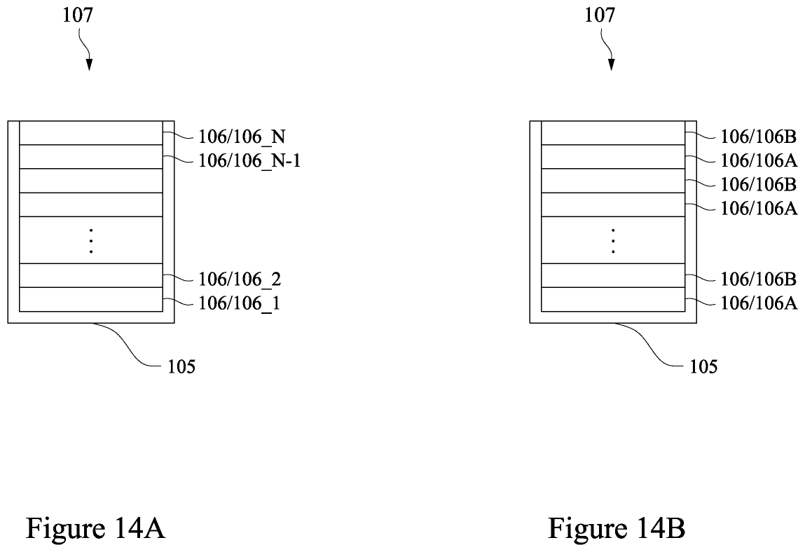

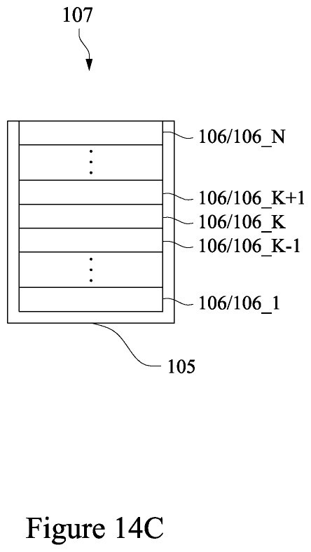

Additional embodiments for the isolation structures 107 are shown in FIGS. 14A-14C. Referring temporarily to FIGS. 14A-14C, each of FIGS. 14A-14C illustrates an example of a multiple-layered isolation structure 107. Each of the isolation structures 107 in FIGS. 14A-14C may be used as the isolation structures 107 of the NSFET device 100.

In FIG. 14A, the dielectric layer 106 of the isolation structure 107 has a plurality of sublayers labeled as 106_1, 106_2, . . . , and 106_N. Each of the sublayers has a different respective value for the atomic ratio between nitrogen and silicon. In an embodiment, there is a gradient in the atomic ratios of the sublayers 106_1 to 106_N, and in particular, the atomic ratio between nitrogen and silicon for each sublayer increases along a direction from the bottom sublayer (e.g., 106_1) toward the top sublayer (e.g., 106_N). Note that the gradient in the atomic ratios causes a corresponding gradient in the dielectric constants or the etch rates of the sublayers 106_1 to 106_N, in some embodiments. The sublayers 106_1 to 106_N may have a same thickness, or may have different thicknesses, these and other variations are fully intended to be included within the scope of the present disclosure.

In FIG. 14B, the dielectric layer 106 of the isolation structure 107 has a first set of sublayers 106A and a second set of sublayers 106B interleaved with the first set of sublayers 106A. The first set of sublayers 106A has a same first atomic ratio between nitrogen and silicon, and the second set of sublayers 106B has a same second atomic ratio between nitrogen and silicon different from the first atomic ratio. In an embodiment, the first sublayers 106A are nitrogen-rich layers with the first atomic ratio having a higher value (e.g., 1.4), and the second sublayers 106B are silicon-rich layers with the second atomic ratio having a smaller value (e.g., 1). In another embodiment, the first sublayers 106A are silicon-rich layers with the first atomic ratio having a smaller value (e.g., 1), and the second sublayers 106B are nitrogen-rich layers with the second atomic ratio having a higher value (e.g., 1.4). The first set of sublayers 106 may have a same first thickness, and the second set of sublayers 106 may have a same second thickness, which second thickness may or may not be the same as the first thickness. In some embodiments, the thickness of each of the sublayers may be individually specified.

In FIG. 14C, the dielectric layer 106 of the isolation structure 107 has a plurality of sublayers. A mid-sublayer 106_K (e.g., at a middle position between the bottommost sublayer 106_1 and the topmost sublayer 106_N) has the highest atomic ratio between nitrogen and silicon, and the atomic ratios in other sublayers decreases along directions from the mid-sublayer 106_K toward the bottommost sublayer 106_1 and toward the topmost sublayer 106_N. In other words, the atomic ratio between nitrogen and silicon decreases from the mid-sublayer 106_K to both ends (106_K and 106_N) of the sublayers, and the sublayers 106_1 and 106_N have the lowest atomic ratio between nitrogen and silicon.

Referring back to FIGS. 7A-7C, the isolation structures 107 are formed at the bottoms of the openings 110, and separate the subsequently formed source/drain regions 112 from the underlying fins 90. The isolation structures 107 advantageously reduce or prevents leakage current between, e.g., a first source/drain region 112 and a neighboring source/drain region 112 of a different type (e.g., n-type or p-type), thereby improving device performance and reducing power consumption.

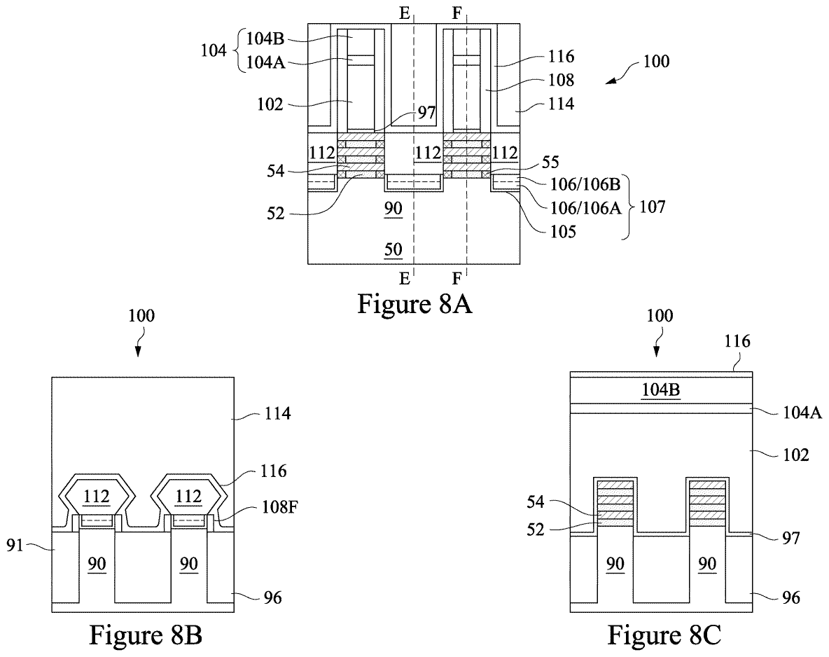

Next, in FIGS. 8A-8C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, a pre-cleaning process comprising one or more etching steps is performed to clean the openings 110 in preparation for (e.g., before) forming the epitaxial source/drain regions 112.

In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110, e.g., on the sidewalls of the second semiconductor material 54 then merging to fill the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 8B) after the epitaxy process is completed. In other embodiments, these facets cause adjacent epitaxial source/drain regions 112 of a same NSFET to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. FIGS. 8B and 8C illustrate cross-sectional views of the NSFET device 100 of FIG. 8A, but along cross-section E-E and F-F in FIG. 8A, respectively.

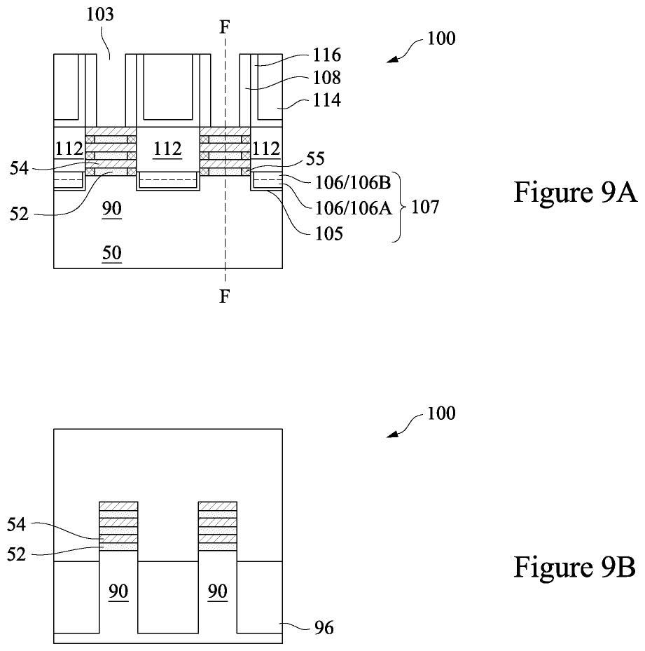

Next, in FIGS. 9A and 9B, the dummy gates 102 are removed. To remove the dummy gates 102, a planarization process, such as a CMP, is performed to level the top surfaces of the first ILD 114 and CESL 116 with the top surfaces of the dummy gates 102 and gate spacers 108. The planarization process may also remove the masks 104 (see FIG. 8A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102 are exposed through the first ILD 114.

Next, the dummy gates 102 are removed in an etching step(s), so that recesses 103 are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. Each recess 103 exposes a channel region of the NSFET. Each channel region is disposed between neighboring pairs of the epitaxial source/drain regions 112. During the removal of the dummy gates 102, the dummy gate dielectric 97 may be used as an etch stop layer when the dummy gates 102 are etched. The dummy gate dielectric 97 may then be removed after the removal of the dummy gates 102. FIG. 9B illustrates the cross-sectional view of the NSFET device 100 of FIG. 9A along the cross-section F-F.

Next, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97.

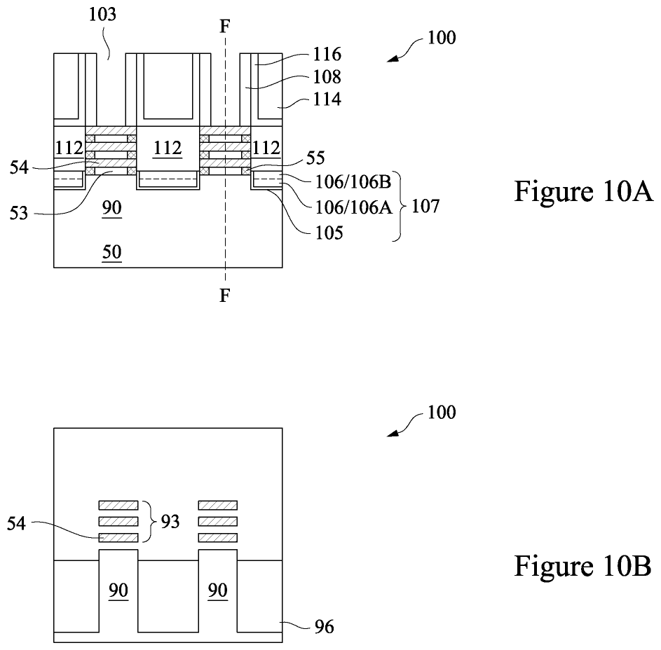

Next, in FIGS. 10A and 10B, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100 formed. As illustrated in FIG. 10A, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas, where the etching gas comprises F₂ and HF, and the carrier gas may be an inert gas such as Ar, He, N₂, combinations thereof, or the like, in some embodiments.

FIG. 10A illustrates the cross-sectional view of the NSFET device 100 along a longitudinal axis of the fin (e.g., along a current flow direction in the fin), and FIG. 10B illustrates the cross-sectional view of the NSFET device 100 along cross-section F-F, which is a cross-section along a direction perpendicular to the longitudinal axis of the fin and across a middle portion of the nanostructure 54.

As illustrated in FIG. 10A, each of the nanostructures 54 has a rectangular shaped cross-section along the longitudinal axis of the fin. Similarly, in FIG. 10B, in a cross-section along a direction perpendicular to the longitudinal axis of the fin and across a middle portion of the nanostructure 54, each of the nanostructures 54 has a rectangular shaped cross-section.

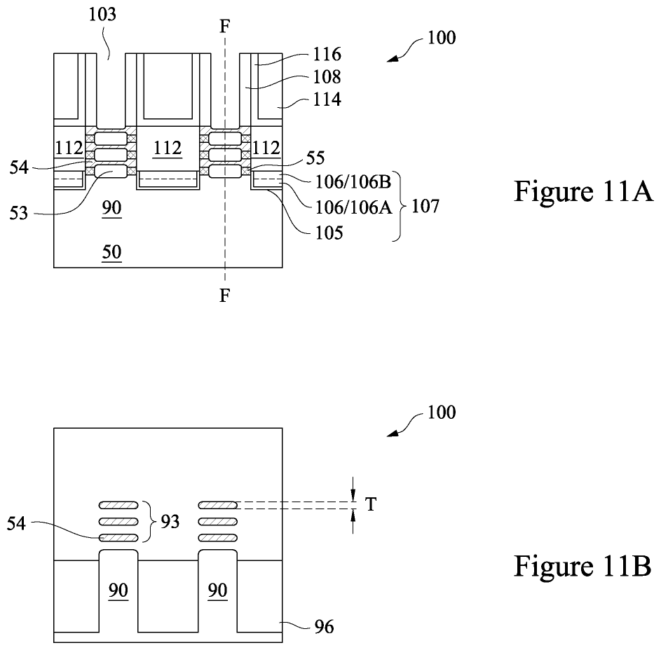

Next, in FIGS. 11A and 11B, the nanostructures 54 are reshaped by a nanostructure reshaping process (e.g., an isotropic etching process). In some embodiments, the nanostructures 54 are reshaped by a selective etching process using an etchant that is selective to the material of the nanostructures 54 (e.g., the second semiconductor material 54), such that the nanostructures 54 are etched without substantially attacking other materials in the NSFET device 100, such as oxide, silicon nitride, and low-K dielectric materials.

In some embodiments, the isotropic etching process (e.g., a selective etching process) to reshape the nanostructures 54 is performed using an etching gas, and optionally, a carrier gas, where the etching gas comprises F₂ and NH₃, and the carrier gas may be an inert gas such as Ar, He, N₂, combinations thereof, or the like.

Besides using a mixture of F₂ and NH₃ as the etching gas, other suitable etching gases, such as ClF₃, or a mixture of NF₃ and NH₃, may alternatively be used as the etching gas to reshape the nanostructures 54. For example, an isotropic etching process (e.g., an isotropic plasma etching process) using an etching gas comprising NF₃ and NH₃ may be performed to reshape the nanostructures 54.

The nanostructure reshaping process thins the middle portion of each nanostructure 54 while the end portions of the nanostructure 54 remain substantially unchanged, thus generating a dumbbell shaped cross-section for the nanostructure 54 in FIG. 11A. In addition, the nanostructure re-shaping process removes the sharp edges (e.g., see the 90-degree edges of the nanostructures 54 in FIG. 10B) of the nanostructures 54, thus generating rounded edges for each nanostructure 54 (see the rounded corners of each nanostructure 54 in FIG. 11B), as described in more details below.

As illustrated in FIG. 11A, after the nanostructure reshaping process, in the cross-section along the longitudinal axis of the fin, each of the nanostructures 54 has a dumbbell shape, where end portions of the nanostructure 54 (e.g., portions physically contacting the source/drain regions 112) have a thickness (measured along the vertical direction of FIG. 11A) larger than that of the middle portion (e.g., a portion mid-way between the end portions). In some embodiments, a difference between the thicknesses of the end portion of the nanostructure 54 and the middle portion of the nanostructure 54 is between about 0 nm and about 3 nm. In the example of FIG. 11A, the upper surface and the lower surface of the middle portion of each nanostructure 54 are illustrated as level surfaces (e.g., flat surfaces). This is, of course, merely a non-limiting example. In some embodiments, the upper surface and lower surface of the middle portion of each nanostructure 54 are curved, such as curved toward a horizontal center axis of the nanostructure 54. In addition, in the cross-section of FIG. 11B, each of the nanostructures 54 has a stadium shape (may also be referred to as a racetrack shape, a discorectangle shape, an obround shape, or a sausage body shape). In particular, in the cross-section of FIG. 11B, the corners of each nanostructure 54 are rounded (e.g., curved). In some embodiments, a thickness T of the nanostructure 54, measured in the middle portion, is between about 3 nm and about 7 nm.

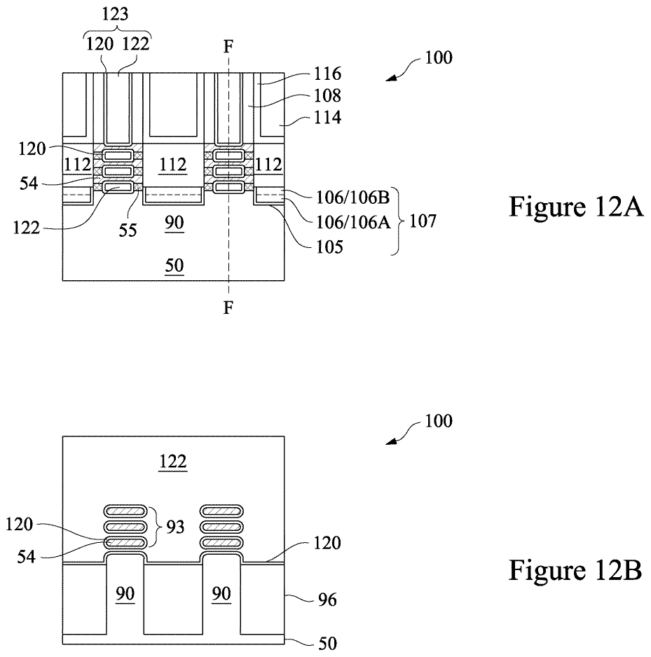

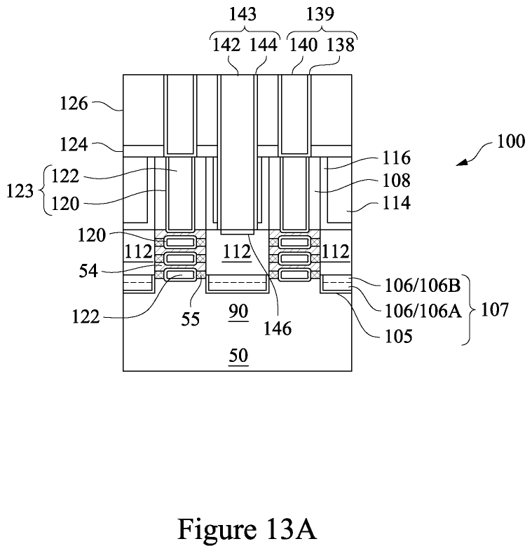

As feature sizes continue to shrink in advanced processing nodes, the distance between adjacent nanostructures 54 may become so small that it may be difficult to form layers (e.g., gate dielectric layer) around the nanostructures 54 in subsequent processing. By reshaping the nanostructures 54, e.g., thinning the middle portions of the nanostructures 54, the distance between adjacent nanostructures 54 is increased, thus making it easier to form, e.g., gate dielectric layer 120 (see FIGS. 12A and 12B) around the nanostructures 54. In addition, since the thickness T of the nanostructures 54, which form the channel regions 93 of the NSFET device 100, is reduced by the nanostructure reshaping process, it is easier to control (e.g., turning on or off) the NSFET device 100 by applying a gate control voltage on the metal gate formed in subsequent processing.

In some embodiments, the nanostructure reshaping process illustrated in FIGS. 11A and 11B is omitted. In subsequent figures, the channel regions 93 of the NSFET device 100 are illustrated as having the cross-sections of FIGS. 11A and 11B, with the understanding that the channel regions 93 may have the cross-sections of FIGS. 10A and 10B (e.g., when the nanostructure reshaping process is omitted).

Next, in FIGS. 12A and 12B, gate dielectric layers 120 and gate electrodes 122 are formed for replacement gates. The gate dielectric layers 120 are deposited conformally in the recesses 103, such as on the top surfaces and the sidewalls of the semiconductor fin 90, and on sidewalls of the gate spacers 108. The gate dielectric layers 120 may also be formed on the top surface of the first ILD 114. Notably, the gate dielectric layers 120 wrap around the nanostructures 54. In accordance with some embodiments, the gate dielectric layers 120 comprise silicon oxide, silicon nitride, or multilayers thereof. In some embodiments, the gate dielectric layers 120 include a high-k dielectric material, and in these embodiments, the gate dielectric layers 120 may have a k value greater than about 7.0, and may include a metal oxide or a silicate of Hf, Al, Zr, La, Mg, Ba, Ti, or Pb, or combinations thereof. The formation methods of the gate dielectric layers 120 may include Molecular-Beam Deposition (MBD), ALD, PECVD, and the like.

Next, the gate electrodes 122 are deposited over and around the gate dielectric layers 120, and fill the remaining portions of the recesses 103. The gate electrodes 122 may include a metal-containing material such as TiN, TiO, TaN, TaC, Co, Ru, Al, W, combinations thereof, or multi-layers thereof. For example, although a single layer gate electrode 122 is illustrated, the gate electrode 122 may comprise any number of liner layers (e.g., barrier layers), any number of work function tuning layers, and a fill material. After the filling of the gate electrodes 122, a planarization process, such as a CMP, may be performed to remove the excess portions of the gate dielectric layers 120 and the material of the gate electrodes 122, which excess portions are over the top surface of the first ILD 114. The remaining portions of material of the gate electrodes 122 and the gate dielectric layers 120 thus form replacement gates of the resulting NSFET device 100. Each gate electrode 122 and the corresponding gate dielectric layers 120 may be collectively referred to as a gate stack 123, a replacement gate structure 123, a metal gate structure 123, or a gate structure 123. Each gate structure 123 extends around the respective nanostructures 54.

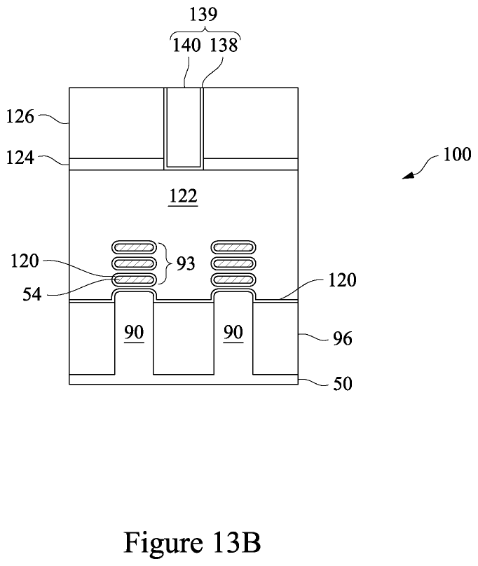

Next, in FIGS. 13A and 13B, an etch stop layer 124 is formed over the first ILD 114 and over the gate structure 123, and a second ILD 126 is formed over the etch stop layer 124. In some embodiments, the etch stop layer 124 is omitted, and the second ILD 126 is formed directly on the first ILD 114.

The etch stop layer 124 is formed of a material different from that of the first ILD 114. For example, the etch stop layer 124 may be formed of silicon nitride, silicon oxynitride, or the like, by a suitable formation method such as CVD, ALD, or the like. The second ILD 126 may be formed of a same or similar material as the first ILD 114, using a same or similar formation method, thus details are not repeated.

Next, source/drain vias 143 (may also be referred to as source/drain contacts) are formed that extend through the second ILD 126, the etch stop layer 124 (if formed), the first ILD 114, and the CESL 116 to be electrically coupled to the source/drain regions 112. For simplicity, FIG. 13A may only illustrate one source/drain via 143, with the understanding that each source/drain region 112 may have a respective overlying source/drain via 143 coupled to the source/drain region 112. Each source/drain via 143 may comprise a barrier layer 144 and an electrically conductive material 142. In addition, a silicide region 146 may be formed over each source/drain region 112 before the corresponding source/drain via 143 is formed.

In some embodiments, to form the source/drain vias 143, openings are formed in the second ILD 126, the etch stop layer 124 (if formed), the first ILD 114, and the CESL 116 to expose the respective underlying source/drain regions 112. Next, the barrier layer 144 is formed (e.g., conformally) to line the bottoms and the sidewalls of the openings. The barrier layer 144 may comprise an electrically conductive material such as titanium nitride, although other materials, such as tantalum nitride, titanium, tantalum, or the like, may also be utilized. The barrier layer may be formed using a CVD process, such as plasma-enhanced CVD (PECVD). However, other alternative processes, such as sputtering or metal organic chemical vapor deposition (MOCVD), atomic layer deposition (ALD), may alternatively be used.

Next, an anisotropic etching process is performed to remove the barrier layer 144 from the bottoms of the openings for the source/drain vias 143 to expose the underlying source/drain regions 112, while the barrier layer 144 along the sidewalls of the openings for the source/drain vias 143 remain. Next, the silicide regions 146 are formed by first depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 146. The un-reacted portions of the deposited metal are then removed, e.g., by an etching process. Although regions 146 are referred to as silicide regions, regions 146 may also be germanide regions, or silicon germanide regions (e.g., regions comprising silicide and germanide).

Next, the electrically conductive material 142 is formed to fill the openings for the source/drain vias 143. The electrically conductive material 142 may comprise copper, although other suitable materials such as tungsten, cobalt, alloys, doped polysilicon, combinations thereof, or the like, may alternatively be utilized. The electrically conductive material 142 may be formed by depositing a seed layer and then electroplating copper onto the seed layer, filling and overfilling the openings for the source/drain vias 143. Once the openings for the source/drain vias 143 have been filled, excess barrier layer 144 and excess electrically conductive material 142 outside of the openings for the source/drain vias 143 may be removed through a grinding process such as chemical mechanical polishing (CMP), although any suitable removal process may be used. The remaining portions of the barrier layer 144 and the electrically conductive material 142 in the openings form the source/drain vias 143.

FIGS. 13A and 13B further illustrate gate contacts 139, which extend through the second ILD 126 and the etch stop layer 124 (if formed) to electrically couple to gate structures 123. Each gate contacts 139 includes a barrier layer 138 and an electrically conductive material 140. The barrier layer 138 may be the same as or similar to the barrier layer 144, and the electrically conductive material 140 may be the same as or similar to the electrically conductive material 142. The gate contacts 139 may be formed using the same or similar formation method as the source/drain vias 143, and may be formed in the same processing steps as the source/drain vias 143, although the gate contacts 139 may also be formed in separate processing steps from the source/drain vias 143. Details of the formation of gate contacts 139 are not discussed here.

Additional processing may be performed to finish fabrication of the NSFET device 100, as one of ordinary skill readily appreciates, thus details may not be repeated here. For example, interconnect structures that include conductive lines and vias may be formed in the backend-of-the-line (BEOL) processing to interconnect the electrical components formed in/on the substrate 50 to form functional circuits.

Variations of the disclosed embodiments are possible and are fully intended to be included within the scope of the present disclosure. For example, depending on the type of device (e.g., n-type or p-type device) formed, the second semiconductor material 54 may be removed, and the first semiconductor material 52 may remain to form the nanostructures, which nanostructures function as the channel regions of the NSFET device formed. In embodiments where the first semiconductor material 52 remains to form the nanostructures, inner spacers are formed in sidewall recesses in end portions of the second semiconductor material 54 before the second semiconductor material 54 is removed, as one of ordinary skill readily appreciates.

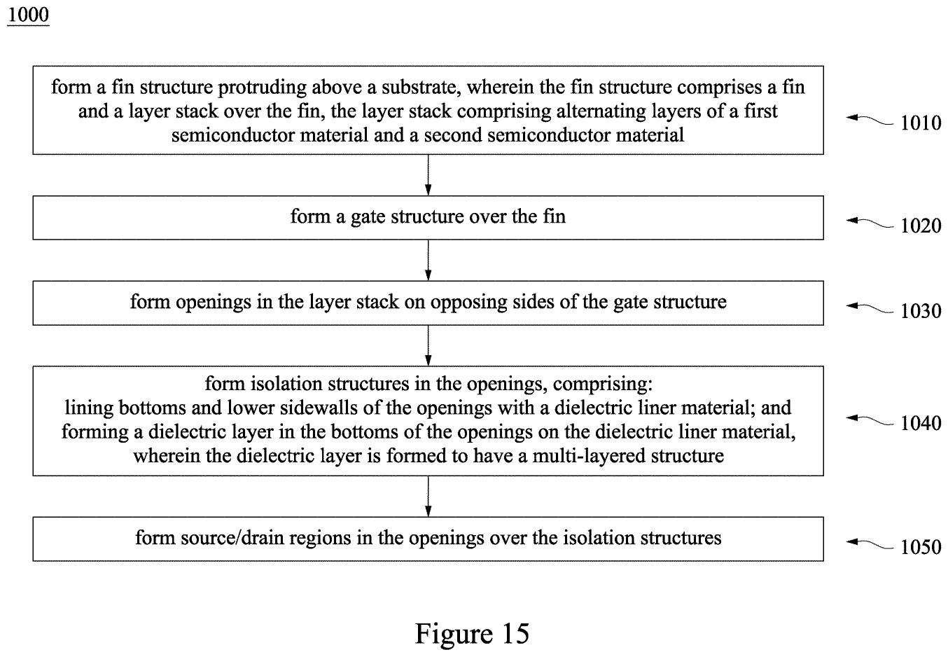

FIG. 15 illustrates a flow chart of a method 1000 of forming a semiconductor device, in accordance with some embodiments. It should be understood that the embodiment method shown in FIG. 15 is merely an example of many possible embodiment methods. One of ordinary skill in the art would recognize many variations, alternatives, and modifications. For example, various steps as illustrated in FIG. 15 may be added, removed, replaced, rearranged, or repeated.

Referring to FIG. 15, at block 1010, a fin structure is formed protruding above a substrate, wherein the fin structure comprises a fin and a layer stack over the fin, the layer stack comprising alternating layers of a first semiconductor material and a second semiconductor material. At block 1020, a gate structure is formed over the fin. At block 1030, openings are formed in the layer stack on opposing sides of the gate structure. At block 1040, isolation structures are formed in the openings, comprising: lining bottoms and lower sidewalls of the openings with a dielectric liner material; and forming a dielectric layer in the bottoms of the openings on the dielectric liner material, wherein the dielectric layer is formed to have a multi-layered structure. At block 1050, source/drain regions are formed in the openings over the isolation structures.

Embodiments may achieve advantages. The disclosed isolation structures isolate source/drain regions from the underlying fins, thereby preventing or reducing leakage current between neighboring source/drain regions. Power consumption of the device formed is reduced and performance is improved. Various aspects of the isolation structures, such as number of sublayers in the dielectric layer 106, the thickness and the etch rate of the sublayers may be tuned to achieve performance targets, and to create large process window for device performance and manufacturing. The disclosed formation methods can be easily integrated into existing manufacturing flow.

In an embodiment, a semiconductor device includes: a substrate; a fin protruding above the substrate; a gate structure over the fin; source/drain regions over the fin and on opposing sides of the gate structure; channel layers over the fin and between the source/drain regions, wherein the gate structure wraps around the channel layers; and isolation structures under the source/drain regions, wherein the isolation structures separate the source/drain regions from the fin, wherein each of the isolation structures comprises a liner layer and a dielectric layer over the liner layer, wherein the dielectric layer has a plurality of sublayers. In an embodiment, the liner layer extends along an upper surface of the fin and along sidewalls of the fin. In an embodiment, the liner layer is a dielectric material and has a U-shaped cross-section, and the dielectric layer fills a space defined by the U-shaped cross-section. In an embodiment, the liner layer has a first dielectric constant, and the dielectric layer has a second dielectric constant higher than the first dielectric constant. In an embodiment, the dielectric layer comprises: a first sublayer comprising silicon nitride, wherein the first sublayer has a first atomic ratio between nitrogen and silicon; and a second sublayer over the first sublayer, wherein the second sublayer comprises silicon nitride and has a second atomic ratio between nitrogen and silicon, wherein the second atomic ratio is different from the first atomic ratio. In an embodiment, the second atomic ratio is lower than the first atomic ratio. In an embodiment, each sublayer of the plurality of sublayers comprises silicon nitride and has a different respective atomic ratio between nitrogen and silicon, wherein there is a gradient in the atomic ratios of the plurality of sublayers. In an embodiment, the atomic ratios of the plurality of sublayers increase along a first direction from a sublayer closest to the substrate to a sublayer furthest from the substrate. In an embodiment, the dielectric layer comprises a first type of sublayers and a second type of sublayers interleaved with the first type of sublayers, wherein each of the first type of sublayers comprises silicon nitride and has a first atomic ratio between nitrogen and silicon, and each of the second type of sublayers comprises silicon nitride and has a second atomic ratio between nitrogen and silicon, wherein the first atomic ratio is different from the second atomic ratio. In an embodiment, the dielectric layer comprises: a first sublayer on the liner layer, the first sublayer comprises silicon nitride and having a first atomic ratio between nitrogen and silicon; a second sublayer over the first sublayer, the second sublayer comprises silicon nitride and having a second atomic ratio between nitrogen and silicon; and a third sublayer over the second sublayer, the third sublayer comprises silicon nitride and having a third atomic ratio between nitrogen and silicon, wherein the second atomic ratio is higher than the first atomic ratio and the third atomic ratio.

In an embodiment, a semiconductor device includes: a substrate; a fin protruding above the substrate; channel layers over the fin; a gate structure over the fin and around the channel layers; source/drain regions over the fin and on opposing sides of the gate structure, wherein the source/drain regions are at opposing ends of the channel layers; and isolation structures between the source/region regions and the fin, wherein the isolation structures comprise a dielectric layer and a dielectric liner layer around the dielectric layer, wherein the dielectric layer has a multi-layered structure. In an embodiment, a first dielectric constant of the dielectric liner layer is different from a second dielectric constant of the dielectric layer. In an embodiment, the semiconductor device further comprises inner spacers between adjacent channel layers and between a lowermost channel layer and the fin, wherein an upper surface of the isolation structures distal from the substrate is between a first surface of a first inner spacer facing away from the substrate and a second surface of the first inner spacer facing the substrate, wherein the first inner spacer is between the lowermost channel layer and the fin. In an embodiment, the dielectric layer comprises a first sublayer and a second sublayer, wherein the first sublayer and the second sublayer comprise silicon nitride and have different atomic ratios between nitrogen and silicon. In an embodiment, the dielectric layer comprises a first set of sublayers and a second set of sublayers interleaved with the first set of sublayers, wherein the first set of sublayers and the second set of sublayers comprise silicon nitride, wherein the first set of sublayers have a first atomic ratio between nitrogen and silicon, and the second set of sublayers have a second atomic ratio between nitrogen and silicon that is different from the first atomic ratio. In an embodiment, the channel layers are nanosheets or nanowires.

In an embodiment, a method of forming a semiconductor device includes: forming a fin structure protruding above a substrate, wherein the fin structure comprises a fin and a layer stack over the fin, the layer stack comprising alternating layers of a first semiconductor material and a second semiconductor material; forming a gate structure over the fin; forming openings in the layer stack on opposing sides of the gate structure; and forming isolation structures in the openings, comprising: lining bottoms and lower sidewalls of the openings with a dielectric liner material; and forming a dielectric layer in the bottoms of the openings on the dielectric liner material, wherein the dielectric layer is formed to have a multi-layered structure. The method further includes forming source/drain regions in the openings over the isolation structures. In an embodiment, the method further comprises, after forming the openings and before forming the isolation structures, replacing end portions of the second semiconductor material exposed by the openings with inner spacers, wherein an upper surface of the isolation structures distal from the substrate is formed to be between an upper surface of a first inner spacer and a lower surface of the first inner spacer, wherein the first inner spacer is an inner spacer closest to the substrate. In an embodiment, forming the dielectric layer comprises: forming a first sublayer of silicon nitride over the dielectric liner material, wherein the first sublayer of silicon nitride has a first atomic ratio between nitrogen and silicon; and forming a second sublayer of silicon nitride over the first sublayer of silicon nitride, wherein the second sublayer of silicon nitride has a second atomic ratio between nitrogen and silicon different from the first atomic ratio. In an embodiment, the method further comprises, after forming the source/drain regions: removing the gate structure to expose the first semiconductor material and the second semiconductor material disposed under the gate structure; removing the exposed first semiconductor material, wherein after removing the exposed first semiconductor material, the second semiconductor material remains to form channel regions of the semiconductor device; and forming a replacement gate structure over and around the channel regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure protruding above a substrate, wherein the fin structure comprises a fin and a layer stack over the fin, the layer stack comprising alternating layers of a first semiconductor material and a second semiconductor material;
forming a gate structure over the fin, the gate structure overlying a first portion of the first semiconductor material and a second portion of the second semiconductor material;
forming a source/drain opening in the layer stack adjacent to the gate structure;
forming an isolation structure in the source/drain opening, comprising:
lining sidewalls and a bottom of the source/drain opening with a liner layer;
forming a dielectric layer on the liner layer and along the sidewalls and the bottom of the source/drain opening, wherein during the forming of the dielectric layer, a deposition rate of the dielectric layer along the sidewalls of the source/drain opening is non-uniform and increases gradually along a depth direction of the source/drain opening; and
removing the liner layer and the dielectric layer from upper sidewalls of the source/drain opening, wherein after the removing, a remaining portion of the liner layer and a remaining portion of the dielectric layer at the bottom of the source/drain opening form the isolation structure; and
forming a source/drain region in the source/drain opening over the isolation structure.

2. The method of claim 1, wherein the dielectric layer is formed to have a non-uniform etch rate that decreases gradually along the depth direction of the source/drain opening.

3. The method of claim 2, wherein forming the dielectric layer comprises performing a deposition process to form the dielectric layer, wherein parameters of the deposition process are adjusted gradually to achieve the non-uniform etch rate of the dielectric layer.

4. The method of claim 2, wherein forming the dielectric layer comprises:
performing a deposition process to form the dielectric layer; and
after performing the deposition process, treating the dielectric layer with a plasma process to adjust the etch rate of the dielectric layer along the depth direction of the source/drain opening.

5. The method of claim 2, wherein removing the liner layer and the dielectric layer comprises:
removing the liner layer from the upper sidewalls of the source/drain opening before forming the dielectric layer; and
after forming the dielectric layer, removing the dielectric layer from the upper sidewalls of the source/drain opening such that an upper surface of the dielectric layer distal from the substrate is level with an upper surface of the liner layer.

6. The method of claim 2, wherein the dielectric layer is formed to have a multi-layered structure that includes a plurality of sublayers.

7. The method of claim 6, wherein forming the dielectric layer comprises:
forming a first sublayer over and in contact with the liner layer, wherein the first sublayer comprises silicon nitride and has a first atomic ratio between nitrogen and silicon; and
forming a second sublayer over and in contact with the first sublayer, wherein the second sublayer comprises silicon nitride and has a second atomic ratio between nitrogen and silicon, wherein the second atomic ratio is different from the first atomic ratio.

8. The method of claim 6, wherein forming the dielectric layer comprises:
forming a lower sublayer over and in contact with the liner layer;
forming one or more additional sublayers sequentially over the lower sublayer; and
forming an upper sublayer over the one or more additional sublayers, wherein each sublayer of the plurality of sublayers comprises silicon nitride and has a different respective atomic ratio between nitrogen and silicon, wherein there is a gradient in the atomic ratios of the plurality of sublayers such that the atomic ratios of the plurality of sublayers increase monotonically along a direction from the lower sublayer to the upper sublayer.

9. The method of claim 6, wherein the dielectric layer comprises a first type of sublayers and a second type of sublayers interleaved with the first type of sublayers, wherein a closest distance between the first type of sublayers and the substrate is smaller than a closest distance between the second type of sublayers and the substrate, wherein the first type of sublayers comprise silicon nitride and have a first atomic ratio between nitrogen and silicon, and the second type of sublayers comprise silicon nitride and have a second atomic ratio between nitrogen and silicon, wherein the first atomic ratio is different from the second atomic ratio.

10. The method of claim 9, wherein each of the first type of sublayers has a first thickness, wherein each of the second type of sublayers has a second thickness different from the first thickness.

11. The method of claim 6, wherein each sublayer of the plurality of sublayers of the dielectric layer comprises silicon nitride and has a respective atomic ratio between nitrogen and silicon, wherein the dielectric layer comprises:
a first sublayer over the liner layer;
a second sublayer over the first sublayer, wherein the second sublayer has a highest atomic ratio between nitrogen and silicon among the plurality of sublayers of the dielectric layer;
a third sublayer over the second sublayer, wherein the second sublayer is between the first sublayer and the third sublayer;
a first set of sublayers between the first sublayer and the second sublayer; and
a second set of sublayers between the second sublayer and the third sublayer, wherein the atomic ratios of the plurality of sublayers decrease monotonically along a first direction from the second sublayer to the first sublayer, and decrease monotonically along a second direction from the second sublayer to the third sublayer.

12. The method of claim 2, further comprising, after forming the source/drain region:
removing the gate structure to expose the first portion of the first semiconductor material and the second portion of the second semiconductor material;
removing the first portion of the first semiconductor material, wherein after removing the first portion of the first semiconductor material, the second portion of the second semiconductor material remains to form channel regions of the semiconductor device; and
forming a replacement gate structure around the channel regions.

13. A method of forming a semiconductor device, the method comprising:
forming a fin structure protruding above a substrate, wherein the fin structure comprises a fin and a layer stack over the fin, the layer stack comprising alternating layers of a first semiconductor material and a second semiconductor material;
forming a gate structure over the fin;
forming a source/drain opening in the layer stack on a side of the gate structure, the source/drain opening exposing end portions of the first semiconductor material and end portions of the second semiconductor material;
replacing the end portions of the first semiconductor material exposed by the source/drain opening with inner spacers;
after the replacing, forming an isolation structure at a bottom of the source/drain opening, the isolation structure comprising:
a liner layer along the bottom of the source/drain opening and along lower sidewalls of the source/drain opening; and
a dielectric layer on the liner layer, wherein the liner layer has a first dielectric constant and the dielectric layer has a second dielectric constant higher than the first dielectric constant, wherein the dielectric layer is formed to have a non-uniform etch rate that decreases gradually along a depth direction of the source/drain opening, and wherein an upper surface of the isolation structure distal from the substrate is formed between an upper surface and a lower surface of a lowermost inner spacer of the inner spacers, the lowermost inner spacer being closest to the substrate among the inner spacers; and
forming a source/drain region in the source/drain opening over the isolation structure.

14. The method of claim 13, wherein the dielectric layer is formed to have a multi-layered structure that includes a plurality of sublayers, wherein the plurality of sublayers comprise a first type of sublayers interleaved with a second type of sublayers, wherein a lowermost sublayer of the first type of sublayers is closer to the substrate than a lowermost sublayer of the second type of sublayers, wherein the first type of sublayers comprise silicon nitride and have a first atomic ratio between nitrogen and silicon, and the second type of sublayers comprise silicon nitride and have a second atomic ratio between nitrogen and silicon, wherein the first atomic ratio is lower than the second atomic ratio.

15. The method of claim 14, wherein each of the first type of sublayers has a first thickness, wherein each of the second type of sublayers has a second thickness different from the first thickness.

16. The method of claim 13, wherein the dielectric layer is formed to have a multi-layered structure that includes a plurality of sublayers, wherein each sublayer of the plurality of sublayers of the dielectric layer comprises silicon nitride and has a respective atomic ratio between nitrogen and silicon, wherein the dielectric layer comprises:
a lower sublayer over the liner layer;
a middle sublayer over the lower sublayer, wherein the middle sublayer has a highest atomic ratio between nitrogen and silicon among the plurality of sublayers of the dielectric layer;
an upper sublayer over the middle sublayer;
a first set of sublayers between the lower sublayer and the middle sublayer; and
a second set of sublayers between the middle sublayer and the upper sublayer, wherein the atomic ratios of the plurality of sublayers decrease monotonically along a first direction from the middle sublayer to the lower sublayer, and decrease monotonically along a second direction from the middle sublayer to the upper sublayer.

17. The method of claim 13, further comprising, after forming the source/drain region:
removing the gate structure to expose the first semiconductor material and the second semiconductor material underlying the gate structure;
removing the exposed first semiconductor material, wherein after the removing, the second semiconductor material remains to form channel regions of the semiconductor device; and
forming a replacement gate structure around the channel regions.

18. A method of forming a semiconductor device, the method comprising:
forming a fin structure protruding above a substrate, wherein the fin structure comprises a fin and a layer stack over the fin, the layer stack comprising alternating layers of a first semiconductor material and a second semiconductor material;
forming a dummy gate structure over the fin structure, the dummy gate structure overlying a first portion of the first semiconductor material and a second portion of the second semiconductor material;
forming a source/drain opening in the layer stack adjacent to the dummy gate structure;
forming an isolation structure in the source/drain opening, comprising:
lining sidewalls and a bottom of the source/drain opening with a liner layer;
performing a deposition process to form a dielectric layer on the liner layer and along the sidewalls and the bottom of the source/drain opening, wherein the dielectric layer has a higher dielectric constant than the liner layer, wherein a deposition rate of the dielectric layer during the deposition process is non-uniform such that the deposition rate of the dielectric layer increases along a depth direction of the source/drain opening;
after performing the deposition process, treating the dielectric layer with a plasma process to achieve a non-uniform etch rate for the dielectric layer such that the etch rate of the dielectric layer decreases along the depth direction; and
after treating the dielectric layer, removing the liner layer and the dielectric layer from upper portions of the sidewalls of the source/drain opening, wherein after the removing, a remaining portion of the liner layer and a remaining portion of the dielectric layer at the bottom of the source/drain opening form the isolation structure;
forming a source/drain region in the source/drain opening over the isolation structure;
after forming the source/drain region, removing the dummy gate structure and the first portion of the first semiconductor material, wherein after the removing, the second portion of the second semiconductor material forms nanostructures; and
forming a replacement gate structure around the nanostructures.

19. The method of claim 18, wherein the dielectric layer includes a plurality of sublayers, wherein each sublayer of the plurality of sublayers comprises silicon nitride and has a respective atomic ratio between nitrogen and silicon, wherein the dielectric layer is formed to include:
a first sublayer over and in contact with the liner layer;
a second sublayer over the first sublayer; and
a plurality of third sublayers between the first sublayer and the second sublayer, wherein there is a gradient in the atomic ratios of the plurality of sublayers such that the atomic ratios of the plurality of sublayers increase monotonically along a direction from the first sublayer to the second sublayer.

20. The method of claim 18, wherein the dielectric layer includes a plurality of sequentially formed sublayers, wherein each sublayer of the plurality of sublayers comprises silicon nitride and has a respective atomic ratio between nitrogen and silicon, wherein the dielectric layer is formed to include:
a first sublayer over and in contact with the liner layer;
a second sublayer over the first sublayer;
a third sublayer over the second sublayer;
a plurality of fourth sublayers between the first sublayer and the second sublayer; and
a plurality of fifth sublayers between the second sublayer and the third sublayer; wherein the second sublayer has a highest atomic ratio between nitrogen and silicon among the plurality of sublayers, wherein the atomic ratios of the plurality of sublayers have a first gradient that decreases monotonically along a first direction from the second sublayer to the first sublayer, and have a second gradient that decreases monotonically along a second direction from the second sublayer to the third sublayer.
